(19) United States
(12) Patent Application Publication
(10) Pub. No.: US 2004/0007183 A1
(43) Pub. Date: Jan. 15, 2004

(54) Apparatus and method for the formation of thin films

(75) Inventors: Steven Van Slyke, Pittsford, NY (US); Tsutomu Yamada, Motosu-gun (JP); Ryuji Nishikawa, Gifu-shi (JP); Hiroshi Kanno, Osaka (JP); Hisakazu Takahashi, Nishinomiya-shi (JP); Yoshitaka Nishio, Osaka (JP); Toshio Negishi, Ashigarakami-gun (JP)

Correspondence Address: Finnegan, Henderson, Farabow,, Garrett & Dunner, L.L.P., 1300 I Street, N.W., Washington, DC, 20005-3315, US

(73) Assignee: ULVAC, Inc.

(21) Appl. No.: 10/192,150

(22) Filed: Jul. 11, 2002

(51) Int. Cl. C23C 16/00

(52) U.S. Cl. 118/723 VE; 427/248.1

(57) ABSTRACT

This thin film-forming apparatus comprises a vacuum chamber 2 for forming a thin film on a target material 5, an evaporation source 3 arranged in the chamber 2 and having an evaporation port 33 through which the vapor of a material 40 to be vapor-deposited passes, and a moving mechanism 20 for moving the source 3 towards the widthwise direction of the port 33 between a prescribed waiting position and film-forming position of the source 3. This apparatus further comprises a film-thickness sensor 50 for detecting a film-forming speed of the material 40, which is arranged in a vicinity of the waiting position of the source 3 and on a side of the material 5. The source 3 is positioned opposite to the sensor 50 at the waiting position and is positioned opposite to the material 5 at the film-forming position.

### BACKGROUND OF THE INVENTION

1. Field of the Invention

The present invention relates to an apparatus device for the formation of a thin film as well as a method for the formation of the same.

2. Description of the Related Art

An organic LED element has recently attracted special interest as an element for a full-color flat panel display. The organic LED element is a self-luminous type element in which a fluorescent organic compound emits light rays through electrical excitation and the element of this kind is characterized in that it has a high luminance and a wide visual field angle, that it permits surface light emission and polychromatic light emission and that it is thin. Moreover, the organic LED element it is further characterized in that it is a complete solid element capable of emitting light rays by the application of a DC current at a low voltage on the order of several volts and that the characteristic properties thereof undergo only small changes even at a low temperature.

FIG. 6 is a schematically elevational and sectional side view showing a vacuum evaporation apparatus of the prior art used for the manufacture of a conventional organic LED element.

In the organic thin film-forming apparatus 101 shown in FIG. 6, one or more evaporation sources 103 are positioned below a vacuum chamber 102 and a substrate 104 on which an organic thin film is deposited or formed is arranged above the evaporation source 103. More specifically, this organic thin film-forming apparatus 101 is designed in such a manner that the vapor of an organic material evaporated from the evaporation source 103 is deposited on the surface of the substrate 105 through a mask 104 to thus form an organic thin film in a desired pattern.

However, it has recently been quite difficult to obtain a thin film having a precisely controlled and uniform distribution of film thickness according to any conventional thin film-forming technique. For this reason, the element manufactured by such a conventional technique suffers from deterioration because the light rays emitted from the picture elements are non-uniform and an unexpectedly high current passes through thinner regions on the film and accordingly, the service life of the resulting organic LED element is considerably reduced.

In particular, there are needs for improved determination of the film-forming speed.

### SUMMARY OF THE INVENTION

Accordingly, it is an object of the present invention to solve the foregoing problems associated with the conventional techniques and more specifically to provide an apparatus for forming an organic thin film having a uniform film-thickness distribution by the precise determination of the film-forming speed.

It is another object of the present invention to provide a method for forming an organic thin film free of any defect such as those observed for the organic thin films formed according to the conventional methods.

According to an aspect of the present invention, there is provided a thin film-forming an apparatus comprising a vacuum chamber for forming a thin film on a substrate or a target material, an evaporation source which is arranged in the vacuum chamber and having an evaporation port of long and narrow shape through which the vapor of a material to be vapor-deposited passes, and a moving mechanism for moving the evaporation source towards the widthwise direction of the evaporation port relative to the target material within the vacuum chamber and between a prescribed waiting or stand-by position and film-forming position of the evaporation source with respect to the target material.

In the present invention, the thin film-forming apparatus may further comprise a film-thickness sensor for detecting the film-forming speed of the foregoing material to be vapor-deposited, which is arranged in the vicinity of the waiting position of the evaporation source. The film-thickness sensor may be arranged on a side of the target material.

The foregoing evaporation source is positioned opposite to the film-thickness sensor at the waiting or stand-by position and is positioned opposite to the target material at the film-forming position.

In the present invention, the thin film-forming apparatus may further comprise a control portion connected to the film-thickness sensor and moving mechanism.

In the present invention, the thin film-forming apparatus may further comprise a partition member for partitioning the space between the film-thickness sensor and the target material.

According to another aspect of the present invention, there is a method for forming a thin film on a substrate or a target material within a vacuum chamber comprising the steps of detecting the film-forming speed of a material to be vapor-deposited while an evaporation source having a long and narrow evaporation port through which the vapor of the material to be vapor-deposited passes is arranged at a prescribed waiting or stand-by position and moving the evaporation source towards a prescribed film-forming position relative to the target material in the widthwise direction of the evaporation port on the basis of the film-forming speed thus detected to thus form a thin film on the surface of the target material.

According to the method of the present invention, the film-forming speed of the material to be vapor-deposited is detected while the evaporation source having a long and narrow evaporation port is arranged at a prescribed waiting position and then a thin film is formed by moving the evaporation source towards a prescribed film-forming position relative to the target material in the widthwise direction of the evaporation port. For this reason, the film-forming speed of the evaporation material can easily and precisely be determined.

Moreover, in the method of the present invention, the formation of a thin film can be initiated after the film-forming speed of the evaporation material is sufficiently stabilized and therefore, the resulting thin film has a uniform distribution of the film thickness. This accordingly leads to the prevention of any non-uniformity in the light rays emitted from the picture elements and the efficient production of an organic LED element having a long service life.

### BRIEF DESCRIPTION OF THE DRAWINGS

Preferred embodiments of a thin film-forming apparatus according to the present invention will hereunder be described in more detail with reference to the accompanying drawings, wherein:

FIG. 1A is an elevational and sectional side view of a preferred embodiment of a thin film-forming apparatus according to the present invention, and FIG. 1B is a block diagram showing the constitution of the control system of the same embodiment of the apparatus as shown in FIG. 1A;

FIG. 2A is a side-elevational and sectional side view of the film-forming apparatus shown in FIG. 1A, and FIG. 2B is a plan view of an evaporation source according to the same embodiment of the film-forming apparatus as shown in FIG. 1A;

FIG. 3 is a diagram for explaining the correlation between the evaporation port of the evaporation source and a mask in the same embodiment of the film-forming apparatus as shown in FIG. 1A;

FIG. 4 is an elevational and sectional side view of the same apparatus as shown in FIG. 1A, in which the evaporation source lies at the waiting position, for carrying out an embodiment of a method for forming a thin film according to the present invention;

FIG. 5 is an elevational and sectional side view of the same apparatus as shown in FIG. 1A, in which the evaporation source lies at the waiting position, for carrying out the embodiment of a method for forming a thin film according to the present invention; and

FIG. 6 is a schematically elevational and sectional side view showing a vacuum vapor deposition apparatus of the prior art used for the formation of a conventional organic LED element.

### DESCRIPTION OF THE PREFERRED EMBODIMENTS

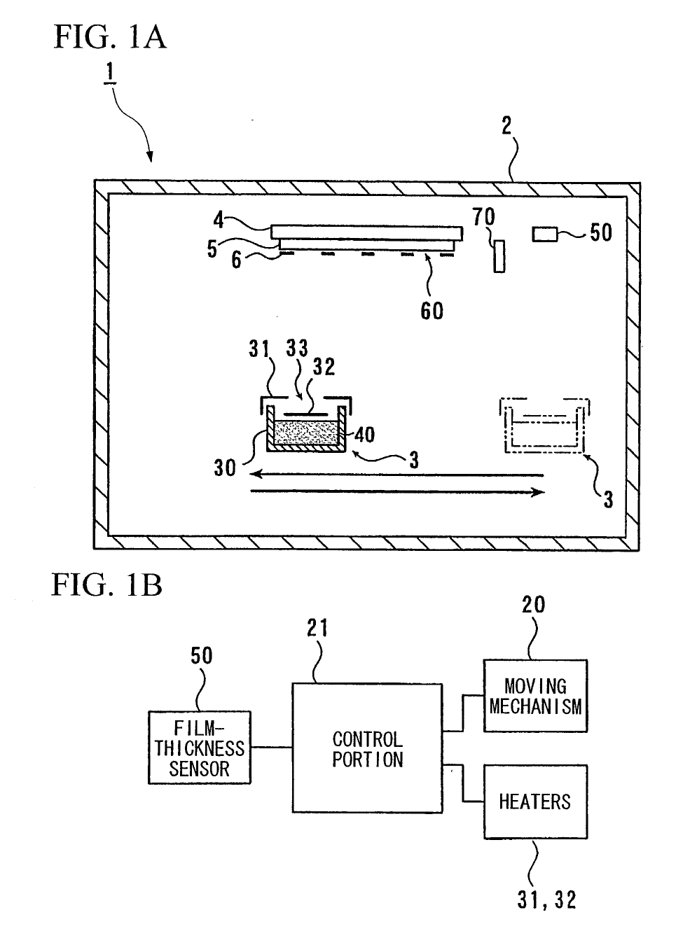

FIG. 1A is an elevational and sectional side view of a preferred embodiment of a thin film-forming apparatus according to the present invention and FIG. 1B is a block diagram showing the constitution of the control system of the same embodiment of the apparatus as shown in FIG. 1A.

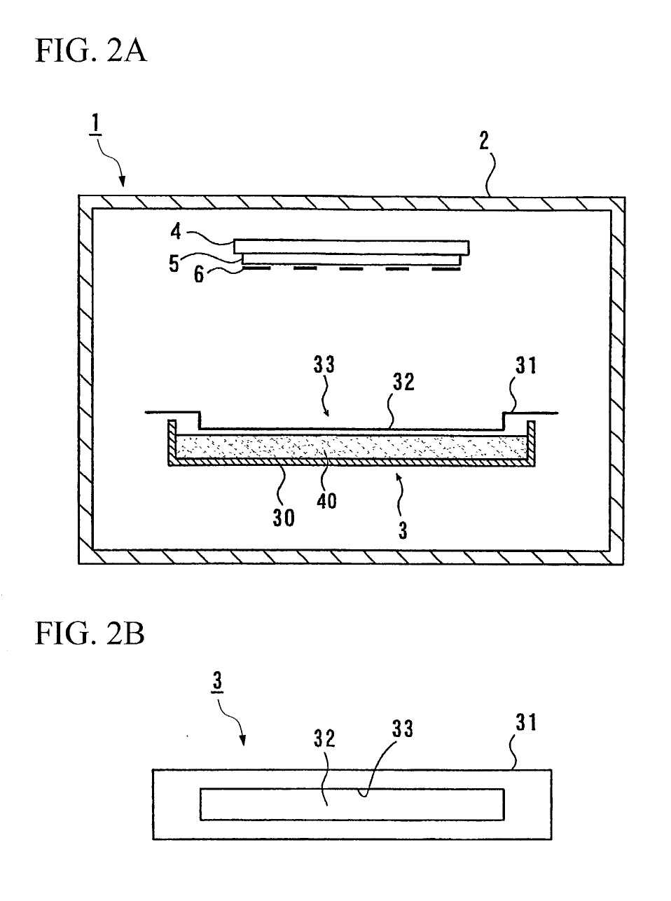

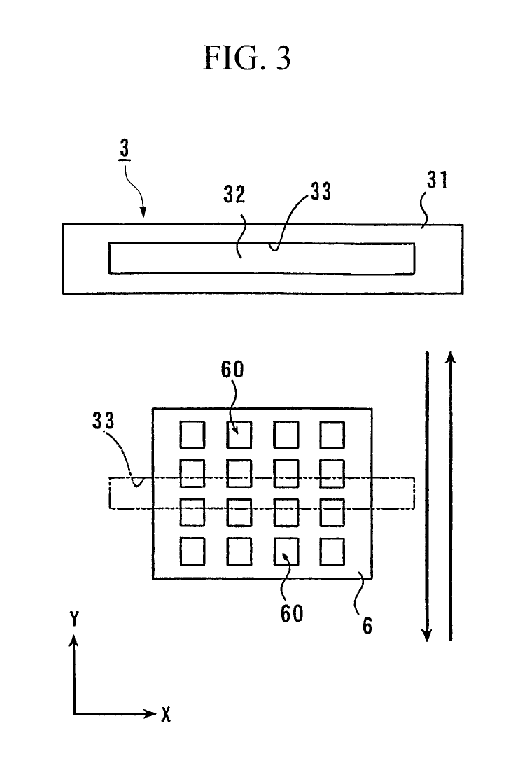

Moreover, FIG. 2A is a side-elevational and sectional side view of the film-forming apparatus shown in FIG. 1A, and FIG. 2B is a plan view of an evaporation source according to the same embodiment of the film-forming apparatus as shown in FIG. 1A. In addition, FIG. 3 is a diagram for explaining the correlation between the evaporation port of the evaporation source and a mask in the same embodiment of the film-forming apparatus as shown in FIG. 1A.

First of all, referring to FIG. 1A, a thin film-forming apparatus 1 according to an embodiment of the present invention comprises a vacuum chamber 2 connected to a vacuum exhaust system (not shown in this figure) and an evaporation source 3 positioned below the vacuum chamber 2.

In the case of this embodiment, as shown in FIG. 2, the evaporation source 3 has a container 30 having a rectangular shape and a desired organic material 40 to be vapor-deposited (for instance, Alq3 (tris-(8-hydroxyquinoline)aluminum(III))) is accommodated in the container 30. Moreover, the evaporation source 3 is so designed that heaters 31, 32 positioned in the vicinity of and above the container 30 can heat the evaporation material 40.

In this respect, a long and narrow evaporation port 33 having a rectangular shape is formed on the upper heater 31 and thus the film-forming apparatus according to this embodiment is so designed that the vapor of the material 40 to be vapor-deposited is towards a substrate (a target material) 5, on which a vapor deposition film is to be formed, while the vapor passes through the evaporation port 33.

On the other hand, a substrate holder 4 is arranged above the vacuum chamber 2 and the substrate (the target material) 5 on which a vapor deposition film is to be formed is fixed to this substrate holder 4. Moreover, a mask 6 having a desired pattern is positioned in the vicinity of and below the substrate 5.

In the case of this embodiment, a plurality of element patterns 60 for depositing a desired thin film on the surface of the substrate 5 are formed on the mask 6, as will be seen from FIG. 3.

In this embodiment, the evaporation source 3 is so designed that it is relatively moved using, for instance, a moving mechanism 20 provided with a ball screw (not shown) as shown in FIGS. 1A and 1B. This moving mechanism 20 is connected to a control portion 21 as will be detailed later, and the mechanism 20 can thus be controlled on the basis of a desired program.

As shown in FIG. 1A, the evaporation source 3 according to this embodiment is so designed that it is moved relative to the substrate 5 using, for instance, a ball screw (not shown).

In this case, the evaporation source 3 is so designed that it can move towards the widthwise direction of the evaporation port 33 and that it can perform reciprocating motion relative to the substrate 5.

In addition, the moving range of the evaporation source 3 extends from the waiting position indicated by two-dot chain lines in FIG. 1A till the evaporation source 3 completely crosses the whole surface of the substrate 5.

In this connection, arrows shown in FIG. 1A stand for the moving range of the central axis of the evaporation port 33 fitted to the evaporation source 3.

In addition, a film-thickness sensor 50 for the determination of the film-forming speed is arranged within and above the vacuum chamber 2.

According to this embodiment, the film-thickness sensor 50 is arranged above the evaporation port 33 of the evaporation source 3, which is disposed at the waiting position (FIG. 1A). Moreover, this film-thickness sensor 50 is connected to the foregoing control portion 21 (FIG. 1B).

Furthermore, a partition member 70 is disposed in the vicinity of the film-thickness sensor 50, which partitions the space formed between the film-thickness sensor 50 and the substrate 5.

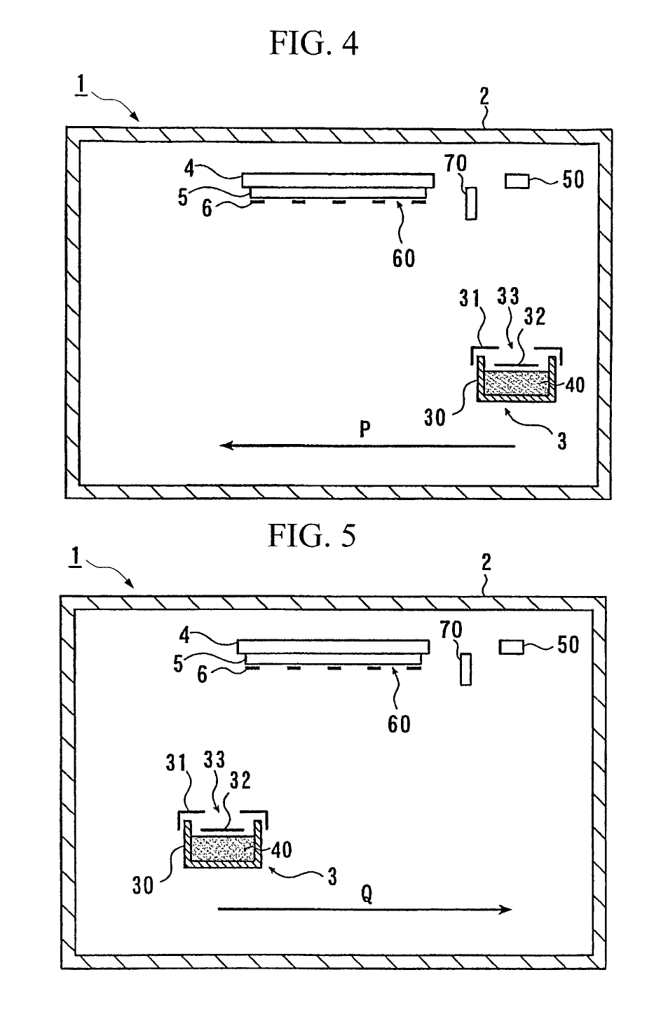

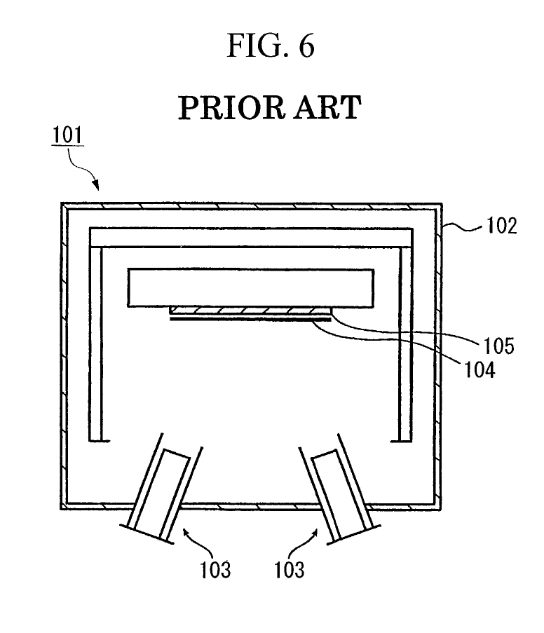

FIGS. 4 and 5 are elevational and sectional side views of the same device as shown in FIG. 1A, carrying out an embodiment of the method for forming a thin film according to the present invention.

In this embodiment of the method according to the present invention, a substrate 5 is first introduced into a vacuum chamber 2 and heaters 31, 32 are electrically charged while an evaporation source 3 is positioned at a waiting position as shown in FIG. 4 to thus initiate the evaporation of a material 40 to be vapor-deposited.

Then the film-forming speed of the material 40 to be vapor-deposited flowing out of the evaporation port 33 of the evaporation source 3 is detected by the film-thickness sensor 50, and the evaporation source 3 is moved towards the film-forming position along the arrow P at an instance when the film-forming speed arrives at a desired level.

Immediately after the movement of the evaporation source 3, the temperature of the heaters 31, 32 fitted to the evaporation source 3 is controlled to maintain the temperature of the material 40 to be vapor-deposited to a desired level and the film-forming speed of the material 40 to be vapor-deposited can thus be adjusted to a constant level 10 form a uniform thin film.

As will be seen from FIG. 5, the evaporation source 3 is moved towards the waiting position along the arrow Q after the evaporation port 33 of the evaporation source 3 crosses the whole surface of the substrate 5. In this case, the temperature of the heaters 31, 32 for the evaporation source 3 is controlled until the evaporation port 33 of the evaporation source 3 completely crosses the whole surface of the substrate 5.

Then the electrical charging of the heaters 31,32 are shut down at an instance when the evaporation port 33 of the evaporation source 3 crosses the whole surface of the substrate 5. Accordingly, any material 40 to be vapor-deposited does not flow out of the evaporation port 33 when the evaporation source 3 returns back to the waiting position.

Thereafter, the substrate 5 is withdrawn from the vacuum chamber 2, then an unprocessed substrate 5 is introduced into the vacuum chamber 2 and the foregoing steps are repeated.

As has been discussed above in detail, in this embodiment of the method according to the present invention, the thin film is formed by moving the evaporation source 3 towards the film-forming position after detecting the film-forming (deposition) speed using the film-thickness sensor 50 while the evaporation source 3 is disposed at the waiting position. Therefore, the film-forming speed of the material 40 to be vapor-deposited can easily and precisely be detected in advance or before deposition.

Moreover, according to this embodiment of the method of the present invention, the thin film can be formed after the film-forming speed of the material 40 to be vapor-deposited is sufficiently stabilized and therefore, the resulting thin film has a uniform distribution of the film thickness. This accordingly leads to the prevention of any non-uniformity in the light rays emitted from the picture elements and the efficient production of an organic LED element having a long service life.

Moreover, in this embodiment of the method according to the present invention, the film-forming speed during the film-forming step is adjusted by controlling the temperature of the material 40 to be vapor-deposited through the control of the heaters 31, 32 and therefore, the film-forming speed can easily be maintained at a uniform level. In addition, the evaporation source 3 is moved away from the film-thickness sensor 50. Therefore, the amount of the material 40 to be vapor-deposited, which is adhered to the film-thickness sensor 50, can substantially be reduced and it is not necessary to frequently perform the maintenance of the film-thickness sensor 50.

In particular, in this embodiment of the method according to the present invention, the film-forming apparatus is equipped with a partition member 70 for partitioning the space formed between the film-thickness sensor 50 and the substrate 5. Therefore, any material 40 to be vapor-deposited does not flow out towards the side of the substrate 5 when the evaporation source 3 is positioned at the waiting position and the material 40 is never adhered to the surface of the substrate 5.

Moreover, any material 40 to be vapor-deposited does not flow out towards the side of the film-thickness sensor 50 during the film-forming step and the material 40 is never adhered to the surface of the film-thickness sensor 50.

Incidentally, the present invention is not restricted to the foregoing embodiments detailed above and the foregoing embodiments can be variously be modified.

For instance, in the foregoing embodiments, the film-forming apparatus is so designed that a thin film is formed by moving an evaporation source, but it is also possible to move the substrate while fixing the evaporation source.

In addition, in the foregoing embodiments, the evaporation source is reciprocated only one time, but it may be reciprocated over at least two times.

Further, the present invention can be applied not only to the apparatus for forming an organic thin film of an organic LED element, but also to a variety of other vapor deposition apparatus. In this connection, the present invention is particularly effective when preparing an organic thin film for an organic LED element using an organic material.

As has been discussed above in detail, the present invention permits the precise determination of the film-forming speed during the film-forming step and in turn the formation of an organic thin film having a uniform film-thickness distribution.

What is claimed is:

1. A film-forming apparatus comprising a vacuum chamber for forming a film on a target material, an evaporation source which is arranged in said vacuum chamber and having an evaporation port of a long and narrow shape through which a vapor of a material to be vapor-deposited passes, and a moving mechanism for moving the evaporation source towards a widthwise direction of said evaporation port relative to said target material within said vacuum chamber and between a prescribed waiting position and film-forming position of the evaporation source with respect to said target material.

2. The film-forming apparatus as set forth in claim 1, wherein said apparatus further comprises a film-thickness sensor for detecting a film-forming speed of said material to be vapor-deposited, which is arranged in a vicinity of said waiting position of said evaporation source.

3. The film-forming apparatus as set forth in claim 1, wherein said apparatus further comprises a film-thickness sensor for detecting a film-forming speed of said material to be vapor-deposited, which is arranged on a side of said target material, said evaporation source is positioned opposite to said film-thickness sensor at said waiting position and is positioned opposite to said target material at said film-forming position.

4. The film-forming apparatus as set forth in claim 2, wherein said apparatus is further so designed that said film-thickness sensor is arranged on a side of said target material, said evaporation source is positioned opposite to said film-thickness sensor at said waiting position and is positioned opposite to said target material at said film-forming position.

5. The film-forming apparatus as set forth in claim 2, wherein said apparatus further comprises a control portion connected to said film-thickness sensor and moving mechanism.

6. The film-forming device as set forth in claim 2, wherein said apparatus further comprises a partition member for partitioning a space between said film-thickness sensor and said target material.

7. The film-forming apparatus as set forth in claim 3, wherein said apparatus further comprises a partition member for partitioning a space between said film-thickness sensor and said target material.

8. The film-forming device as set forth in claim 4, wherein said apparatus further comprises a partition member for partitioning a space between said film-thickness sensor and said target material.

9. A method for forming a film on a target material within a vacuum chamber comprising the steps of detecting a film-forming speed of a material to be vapor-deposited while an evaporation source having a long and narrow evaporation port through which a vapor of said material to be vapor-deposited passes is arranged at a prescribed waiting position and moving said evaporation source towards a prescribed film-forming position relative to said target material in a widthwise direction of said evaporation port on a basis of said film-forming speed thus detected to thus form a thin film on the surface of said target material.
